(19) United States
(12) Patent Application Publication
(10) Pub. No.: US 2025/0166685 A1
(43) Pub. Date: May 22, 2025

(54) READ OFFSET COMPENSATOR FOR ADJUSTING REFERENCE RESISTANCE USING COARSE OFFSET REFERENCE RESISTANCE AND FINE OFFSET REFERENCE RESISTANCE, AND MEMORY DEVICE INCLUDING THE SAME

(71) Applicant: SAMSUNG ELECTRONICS CO., LTD., Suwon-si (KR)

(72) Inventors: Gyuseong KANG, Suwon-si (KR); Dohui KIM, Suwon-si (KR)

(73) Assignee: SAMSUNG ELECTRONICS CO., LTD., Suwon-si (KR)

(21) Appl. No.: 18/900,110

(22) Filed: Sep. 27, 2024

(30) Foreign Application Priority Data
Nov. 16, 2023 (KR) 10-2023-0159237
Mar. 22, 2024 (KR) 10-2024-0039465

(51) Int. Cl. G11C 11/16

(52) U.S. Cl. CPC G11C 11/1673; G11C 11/1653; G11C 11/161

(57) ABSTRACT

Disclosed is a method and a memory device implementing the method. The method may include searching for a number of fail bits of output data output from a memory cell array of the memory device; determining a coarse offset reference resistance; searching for a number of fail bits of a first output data within a first reference resistance range based on the coarse offset reference resistance, determining a first fine offset reference resistance; searching for a number of fail bits of the second output data within a second reference resistance range based on the coarse offset reference resistance, determining a second fine offset reference resistance; and adjusting a reference resistance for a read operation using the coarse offset reference resistance and fine offset reference resistances, the fine offset reference resistances comprising resistances from the first fine offset reference resistance to the second fine offset reference resistance.

### CROSS-REFERENCE TO RELATED APPLICATIONS

This application claims priority under 35 U.S.C. § 119 to Korean Patent Application 10-2024-0039465 filed on Mar. 22, 2024, and to Korean Patent Application No. 10-2023-0159237 filed on Nov. 16, 2023, in the Korean Intellectual Property Office, the disclosures of which are incorporated by reference herein in their entireties.

### BACKGROUND

Example embodiments of the present disclosure described herein relate to a semiconductor memory device, and more particularly, relate to a read offset compensator for adjusting a reference resistance using a coarse offset reference resistance and a fine offset reference resistance, and a memory device including the same.

Semiconductor memories may be classified as a volatile memory or a non-volatile memory, for example. Typically, the volatile memories (e.g., a dynamic random access memory (DRAM) or a static random access memory (SRAM)) may exhibit faster read and/or write speeds when compared to the non-volatile memory. However, data stored in the volatile memory may disappear when a power applied to the volatile memory is turned off. In contrast, the non-volatile memory may retain the data even when the power is turned off.

A magnetoresistive random access memory (MRAM) may include a magnetic tunnel junction (MTJ). The magnetization direction of the MTJ may change according to the direction of the current applied to the MTJ. The resistance value of the MTJ may vary according to the magnetization direction of the MTJ. MRAM may store or read data using these MTJ characteristics.

The MRAM may perform a read operation by comparing the resistance distribution R0 with data 0 and the reference resistance Rref having an intermediate size between the resistance distribution R1 with data 1. However, the resistance distribution of the MRAM may be different for each input/output terminal (I/O) due to mismatches such as MTJ resistance or sense amplifier resistance. If the resistance distribution of the MRAM changes, the read margin for the read operation may decrease.

### SUMMARY

Example embodiments of the present disclosure provide a read offset compensator capable of increasing a read margin through an offset reference resistance compensation, a memory device including the same.

According to an embodiment, a read offset compensator, the read offset compensator including: a coarse offset reference resistance generator configured to: determine whether a number of fail bits of output data of a memory device is less than or equal to a reference value, and determine a coarse offset reference resistance based on the number of fail bits of the output data being less than or equal to the reference value; a first fine offset reference resistance generator configured to: determine a number of fail bits of first output data of the memory device within a first reference resistance range based on the coarse offset reference resistance, determine whether the number of fail bits of the first output data is less than or equal to the reference value, and determine a first fine offset reference resistance based on the number of fail bits of the first output data being less than or equal to the reference value; a second fine offset reference resistance generator configured to: determine a number of fail bits of second output data of the memory device within a second reference resistance range based on the coarse offset reference resistance, determine whether the number of fail bits of the second output data is less than or equal to the reference value, and determine a second fine offset reference resistance based on the number of fail bits of the second output data being less than or equal to the reference value; a first sense amplifier offset compensator configured to: receive the coarse offset reference resistance and the first fine offset reference resistance, and adjust a first offset reference resistance; and a second sense amplifier offset compensator configured to: receive the coarse offset reference resistance and the second fine offset reference resistance, and adjust a second offset reference resistance, wherein each sense amplifier offset compensator from the first sense amplifier offset compensator to the second sense amplifier offset compensator is further configured to: calculate a respective local resistance for compensating a respective offset reference resistance for a respective sense amplifier during offset reference resistance compensation, and adjust a respective reference resistance for a read operation based on the respective local resistance.

According to an embodiment, a memory device including: memory cell array comprising a plurality of memory cells; a row decoder connected to the memory cell array through word lines; a column decoder connected to the memory cell array through bit lines and source lines; a sense amplifier configured to read data stored in selected memory cells by detecting the difference between the source line voltage and the reference voltage during a read operation; and a controller configured to have a read offset compensator for performing an offset reference resistance compensation, wherein the read offset compensator is configured to: receive output data from the sense amplifier, search for a number of fail bits of the output data to determine a coarse offset reference resistance, detect a number of fail bits of first output data within a first reference resistance range based on the coarse offset reference resistance to determine a first fine offset reference resistance, search for a number of fail bits of second output data within a second reference resistance range based on the coarse offset reference resistance to determine a second fine offset reference resistance, and adjust a reference resistance for the read operation using the coarse offset reference resistance and fine offset reference resistances, the fine offset reference resistances comprising resistances from the first fine offset reference resistance to the second fine offset reference resistance.

According to an embodiment, an offset reference resistance compensation method for a memory device, the method being executed by at least one processor, and the method includes searching for a number of fail bits of output data output from a memory cell array of the memory device; determining a coarse offset reference resistance; searching for a number of fail bits of a first output data within a first reference resistance range based on the coarse offset reference resistance, determining a first fine offset reference resistance; searching for a number of fail bits of the second output data within a second reference resistance range based on the coarse offset reference resistance, determining a second fine offset reference resistance; and adjusting a reference resistance for a read operation using the coarse offset reference resistance and fine offset reference resistances, the fine offset reference resistances comprising resistances from the first fine offset reference resistance to the second fine offset reference resistance.

### BRIEF DESCRIPTION OF THE DRAWINGS

The above and other objects and features of the present disclosure will become apparent by describing in detail embodiments thereof with reference to the accompanying drawings.

FIG. 1 is a block diagram illustrating a storage device according to an embodiment of the present disclosure.

FIG. 2 is a block diagram illustrating an example embodiment of the memory device shown in FIG. 1.

FIG. 3 is a circuit diagram illustrating a first memory block of the memory cell array shown in FIG. 2.

FIG. 4 is a block diagram illustrating a memory cell shown in FIG. 3.

FIG. 5 is a block diagram illustrating the first memory cell shown in FIG. 3.

FIG. 6 is a graph illustrating the offset reference resistance generated in the read offset compensator shown in FIG. 2.

FIG. 7 is a graph illustrating the read margin before and after compensating the offset reference resistance.

FIG. 8 is a block diagram illustrating an embodiment of the read offset compensator shown in FIG. 2.

FIG. 9 is a block diagram illustrating an embodiment of the first sense amplifier offset compensator.

FIG. 10 is a block diagram illustrating a configuration of the coarse offset reference resistance generator shown in FIG. 9.

FIG. 11 is a graph illustrating the coarse offset reference resistance generator shown in FIG. 9.

FIG. 12 is a block diagram illustrating a configuration of the first fine offset reference resistance generator shown in FIG. 9.

FIG. 13 is a graph illustrating the first fine offset reference resistance generator shown in FIG. 9.

FIG. 14 is a block diagram illustrating a configuration of the second fine offset reference resistance generator shown in FIG. 9.

FIG. 15 is a graph illustrating the second fine offset reference resistance generator shown in FIG. 9.

FIG. 16 is a block diagram illustrating an embodiment of the first sense amplifier offset compensator shown in FIG. 9.

FIG. 17 is a block diagram illustrating an embodiment of the first sense amplifier offset compensator shown in FIG. 9.

FIG. 18 is a flowchart for a process for offset reference resistance compensation operation of a memory device according to an embodiment of the present disclosure.

### DETAILED DESCRIPTION

Below, example embodiments of the present disclosure will be described in detail and clearly to such an extent that an ordinary one in the art easily implements the inventive concepts.

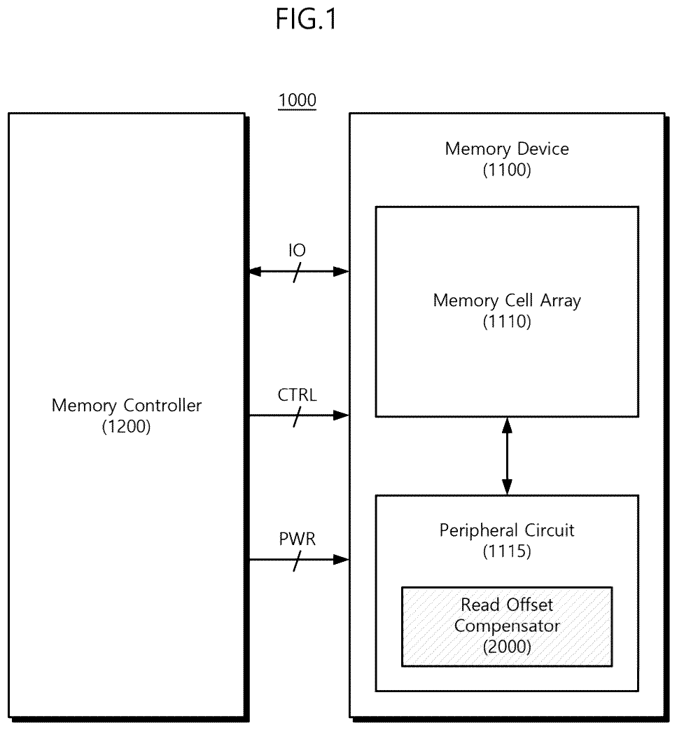

At least one of the components, elements, modules and units (collectively “components” in this paragraph) represented by a block in the drawings such as FIGS. 1, 9 and 10 may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU), a microprocessor, or the like that performs the respective functions.

FIG. 1 is a block diagram illustrating a storage device according to an example embodiment of the present disclosure. The storage device 1000 may be a flash storage device based on a flash memory. For example, the storage device 1000 may be implemented as a solid-state drive (SSD), a universal flash storage (UFS), a memory card, or the like.

Referring to FIG. 1, the storage device 1000 may include a memory device 1100 and a memory controller 1200. The memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

The memory device 1100 may include a memory cell array 1110 and a peripheral circuit 1115. The memory cell array 1110 may include a plurality of memory blocks BLK1 to BLKn. Each memory block may have a vertical 3D structure. Each memory block may include a plurality of memory cells. Multi-bit data may be stored in each memory cell.

The memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure.

In an example embodiment, the memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

The peripheral circuit 1115 may include analog circuits and/or digital circuits required to store data in the memory cell array 1110 or read data stored in the memory cell array 1110. The peripheral circuit 1115 may receive the external power PWR through power lines and generate internal powers of various levels.

The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200.

The peripheral circuit 1115 may include the read offset compensator 2000. The read offset compensator 2000 may search the number of fail bits of the first to n-th output data output from the memory cell array 1110 and determine a coarse offset reference resistance. The read offset compensator 2000 may sequentially search for the number of fail bits of the first to n-th output data within a reference resistance range based on the coarse offset reference resistance and determine the first to n-th fine offset reference resistance. The read offset compensator 2000 may adjust a reference resistance for a read operation using the coarse offset reference resistance and the first to n-th fine offset reference resistances. The memory device 1100 may improve the read margin during a normal read operation through an offset reference resistance compensation operation.

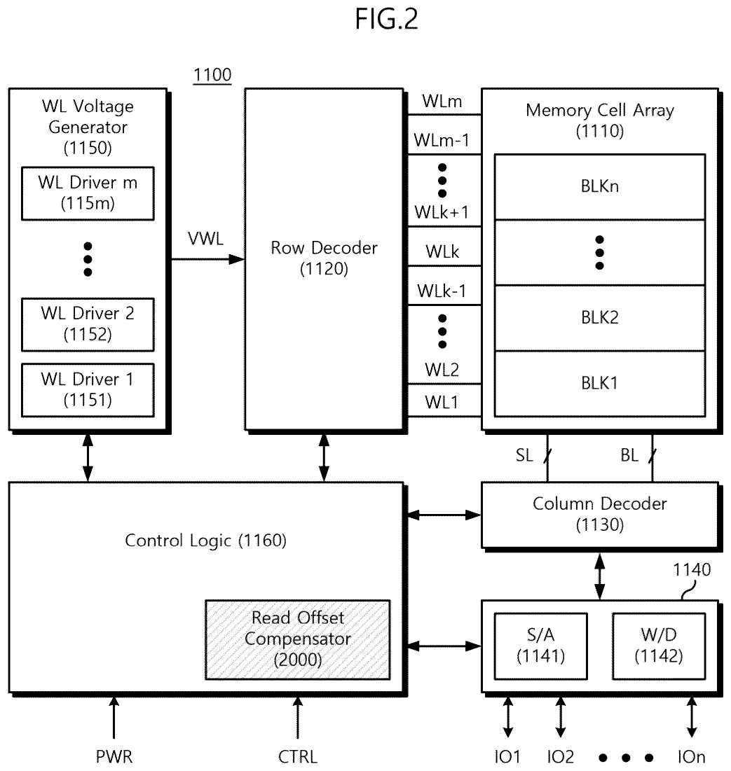

FIG. 2 is a block diagram illustrating an example embodiment of the memory device shown in FIG. 1. The storage device 1000 of FIG. 1 may be a resistive storage device based on a resistive memory. For example, the memory device 1100 may be MRAM, ReRAM, or PRAM.

Referring to FIGS. 1 and 2, The memory device 1100 may include the memory cell array 1110 and the peripheral circuit 1115. The peripheral circuit 1115 may include a row decoder 1120, a column decoder 1130, an input/output circuit 1140, a word line voltage generator 1150, and a control logic 1160.

The memory cell array 1110 may include a plurality of memory blocks BLK1 to BLKn. Each memory block may include a plurality of memory cells. Each memory cell may store multi-bit data. Each memory block (e.g., BLK1) may be connected to a plurality of word lines WL1 to WLm.

The row decoder 1120 may be connected to the memory cell array 1110 through a plurality of word lines WL1 to WLm. The row decoder 1120 may select a word line during a program or read operation. The row decoder 1120 may receive the word line voltage VWL from the word line voltage generator 1150 and provide the word line voltage VWL for a program or read operation to a selected word line.

The column decoder 1130 may be connected to the memory cell array 1110 through source lines SL and/or bit lines BL. The column decoder 1130 may select source lines SL and/or bit lines BL in response to a selection signal provided from the control logic 1160. The column decoder 1130 may select source lines SL and/or bit lines BL using a plurality of NMOS transistors.

The input/output circuit 1140 may be internally connected to the column decoder 1130 through data lines and externally connected to the memory controller 1200 through the input/output lines 101 to IOn. The input/output circuit 1140 may receive program data from the memory controller 1200 during a program operation. Also, the input/output circuit 1140 may provide data read from the memory cell array 1110 to the memory controller 1200 during a read operation.

The input/output circuit 1140 may include a sense amplifier 1141 (referred to in the drawings as “S/A”) and a write driver 1142 (referred to in the drawings as “W/D”). The input/output circuit 1140 may receive or output data from input/output terminals. The number of input/output terminals may vary depending on the type of storage device 1000. The input/output circuit 1140 may provide data to the write driver 1142 in response to a control signal. The input/output circuit 1140 may provide output data provided from the sense amplifier 1141 to an external device.

The sense amplifier 1141 may read data stored in a selected memory cell by sensing a difference between the voltage of a source line, e.g., SL, and the reference voltage, e.g., Vref, during a read operation. The reference voltage may be provided by a reference voltage generator circuit. The sense amplifier 1141 may operate in response to a control signal provided from the control logic 1160.

The write driver 1142 may receive a control signal from the control logic 1160 and provide a program current, e.g., program current I_PGM, to a data line. The program current may be for programming the selected memory cell into one of multi-states. During a multi-level cell (MLC) program operation, the write driver 1142 may provide the program current one or more times according to the multi-state of the selected memory cell.

The word line voltage generator 1150 may receive internal power from the control logic 1160 and generate a word line voltage VWL required to read or write data. The word line voltage VWL may be provided to the selected word line sWL through the row decoder 1120. The word line voltage generator 1150 may include a plurality of word line drivers 1151 to 115m.

The control logic 1160 may control read and/or write operations of the memory device 1100 using commands CMD, addresses ADDR, and control signals CTRL provided from the memory controller. The addresses ADDR may include a row address for selecting one memory block or one word line and a column address for selecting one memory cell.

The control logic 1160 may include the read offset compensator 2000. The read offset compensator 2000 may adjust a reference resistance for a read operation using a coarse offset reference resistance and the first to n-th fine offset reference resistances. The read offset compensator 2000 may compensate the reference resistance Rref by the local resistance calculated during the offset reference resistance compensation operation. Since the memory device 1100 is individually calibrated to have a local resistance to compensate for the offset reference resistance for each sense amplifier. The memory device 1100 may improve read margin during a read operation.

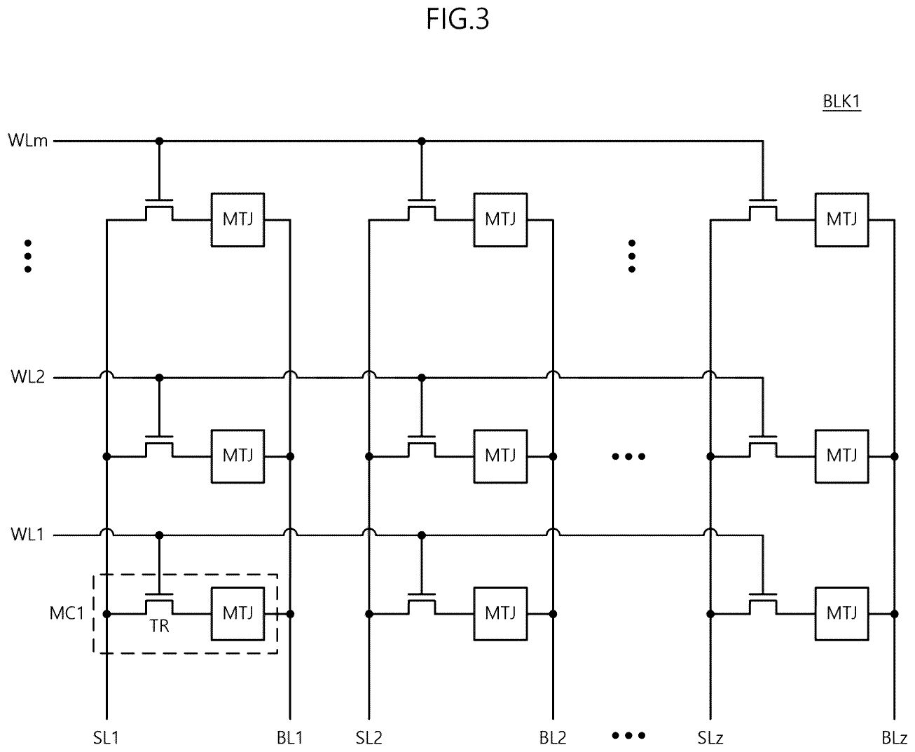

FIG. 3 is a circuit diagram illustrating a first memory block of the memory cell array shown in FIG. 2. Referring to FIG. 3, the memory cell array 1110 may include a plurality of memory cells. Each of the plurality of memory cells may be an MRAM cell and may be connected to word lines (L1 to WLm, bit lines BL1 to BLn, and source lines SL1 to SLn, respectively.

For example, a first memory cell MCi may include an access transistor TR and a variable resistance element MTJ (e.g., a magnetic tunnel junction). A first end of the access transistor TR may be connected with the first source line SL1, a second end of the access transistor TR may be connected with a first end of the variable resistance element MTJ, and a gate of the access transistor TR may be connected with the first word line WL1. A second end of the variable resistance element MTJ may be connected to the first bit line BL1. The first memory cell MCi may store data in the variable resistance element MTJ by adjusting the resistance value of the variable resistance element MTJ.

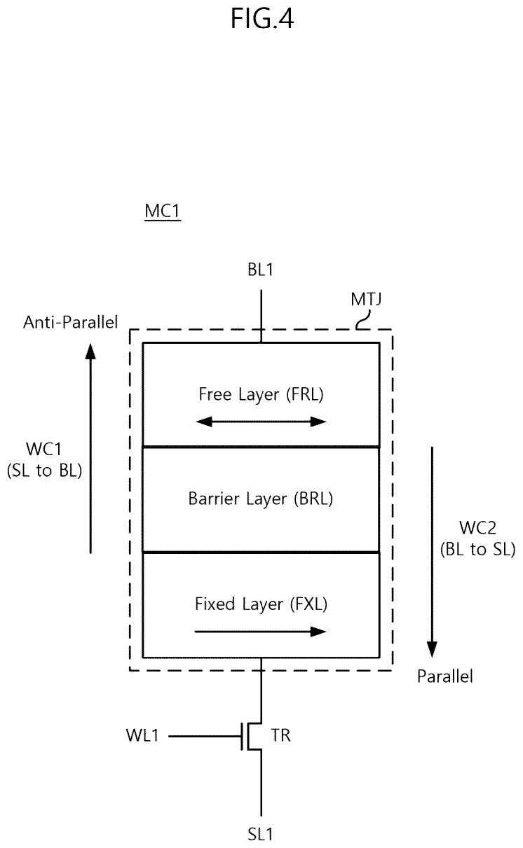

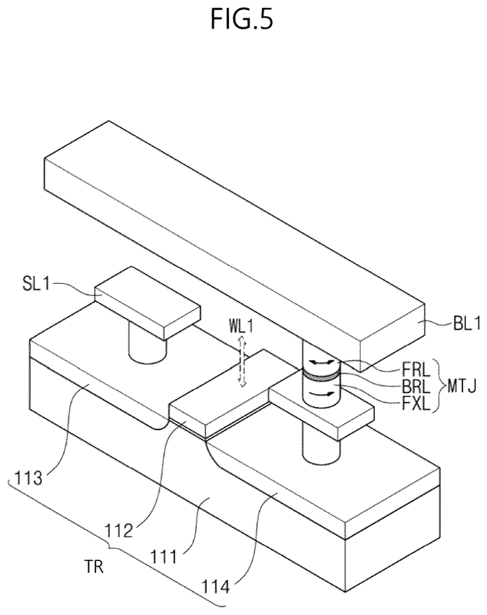

FIGS. 4 and 5 are diagrams for explaining the first memory cell shown in FIG. 3. Referring to FIGS. 4 and 5, the variable resistance element MTJ may include a free layer FRL, a barrier layer BRL, and a fixed layer FXL. The barrier layer BRL may be interposed between the free layer FRL and the fixed layer FXL, the free layer FRL may be connected with the first bit line BL1, and the fixed layer FXL may be connected with the second end of the access transistor TR.

The access transistor TR may include a body substrate 111, a gate electrode 112, and junctions 113 and 114. The junction 113 may be formed on the body substrate 111 and may be connected to the first source line SL1. The junction 114 may be formed on the body substrate 111 and may be connected to the first bit line BL1 through an MTJ element. The gate electrode 112 may be formed on the body substrate 111 between the junctions 113 and 114 and may be connected to the first word line WL1.

A magnetization direction of the fixed layer FXL may be fixed to a specific direction, and a magnetization direction of the free layer FRL may be changed according to a specific condition (e.g., a direction of a write current). According to some embodiments, the variable resistance element MTJ may further include an anti-ferromagnetic layer for fixing the magnetization direction of the fixed layer FXL.

The free layer FRL may include a material which has a variable magnetization direction. The magnetization direction of the free layer FRL may be changed by an electrical/magnetic factor provided from outside and/or inside of a memory cell. The free layer FRL may include a ferromagnetic material that contains at least one of cobalt (Co), iron (Fe), and nickel (Ni). For example, the free layer FRL may include at least one selected from FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. However, the present disclosure is not limited to these examples.

A thickness of the barrier layer BRL may be smaller than a spin diffusion distance. The barrier layer BRL may include a non-magnetic material. For example, the barrier layer BRL may include at least one selected from a group of magnesium (Mg), titanium (Ti), aluminum (Al), oxide of magnesium-zinc (MgZn) and magnesium-boron (MgB), and nitride of titanium (Ti) and vanadium (V). However, the present disclosure is not limited to these examples.

The fixed layer FXL may have a magnetization direction pinned by the anti-ferromagnetic layer. The fixed layer FXL may include a ferromagnetic material. For example, the fixed layer FXL may include at least one selected from a group of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. According to some embodiments, the anti-ferromagnetic layer may include an anti-ferromagnetic material. For example, the anti-ferromagnetic layer may include at least one selected from a group of PtMn, IrMn, MnO, MnS, MnTe, MnF2, FeCl2, FeO, CoCl2, CoO, NiCl2, NiO, and Cr. However, the present disclosure is not limited to these examples.

As illustrated in FIG. 4, the magnetization direction of the free layer FRL may be changed according to a direction of a write current WC1 or WC2 flowing through the variable resistance element MTJ. For example, referring to the first write current WC1 illustrated in FIG. 4, when a current flows in a direction from the first source line SL1 to the first bit line BL1, the magnetization direction of the free layer FRL may be opposite to the magnetization direction of the fixed layer FXL, which corresponds to an anti-parallel state. Referring to the second write current WC2 illustrated in FIG. 4, when a current flows in a direction from the first bit line BL1 to the first source line SL1, the magnetization direction of the free layer FRL may be the same as the magnetization direction of the fixed layer FXL, which corresponds to a parallel state.

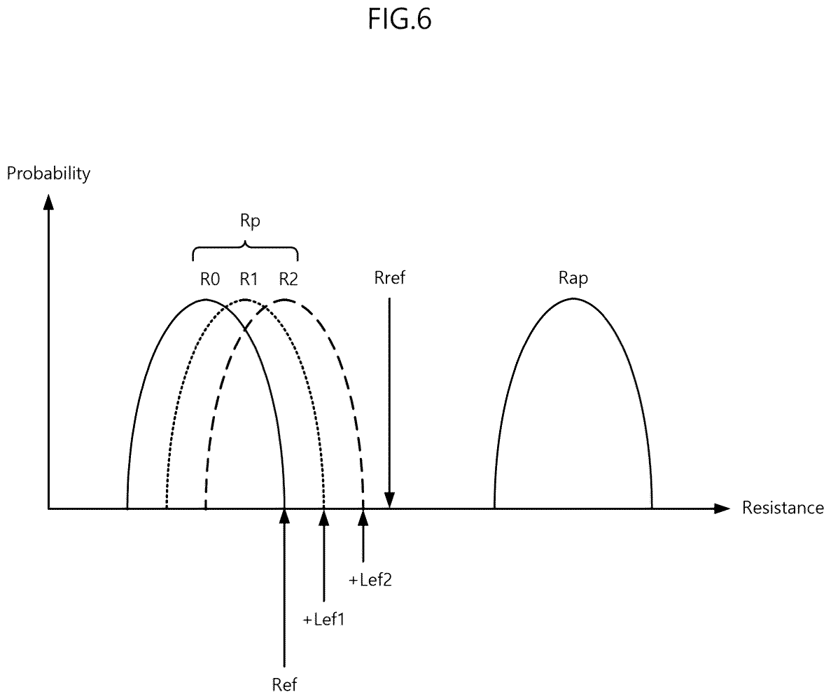

FIG. 6 is a graph for explaining the offset reference resistance generated in the read offset compensator shown in FIG. 2. Referring to FIG. 6, the offset reference resistance Ref is different from the normal reference resistance Rref for distinguishing data 0 and data 1 during a read operation.

When the variable resistance element MTJ is in a semi-balanced state, the variable resistance element MTJ may have an anti-balance resistance Rap. When the variable resistance element MTJ is in a balanced state, the variable resistance element MTJ may have a balance resistance Rp. A balance resistance state may have data 0, and an anti-balance resistance state may have data 1. The memory device 1100 may distinguish data 0 or data 1 using a normal reference resistance Rref.

The offset reference resistance Ref may be a resistance used to control changes in the resistance distribution of the memory device 1100 as shown in FIG. 6 due to mismatches in the MTJ resistance, Rref, and S/A resistance. When the resistance distribution changes from R0 to R1, the offset reference resistance Ref may increase by Lef1. When the resistance distribution changes from R0 to R2, the offset reference resistance Ref may increase by Lef2.

The memory device 1100 may perform a read operation through comparison with a reference resistance Rref having an intermediate level between data 0 and data 1. The reference resistance Rref may be externally changed without using a fixed value when the memory device 1100 is manufactured. The reference resistance may be determined through a test operation. Data may be stored in the first memory cell MCi according to the resistance value of the variable resistance element MTJ. Data stored in the first memory cell MCi may be read by reading the resistance value of the variable resistance element MTJ.

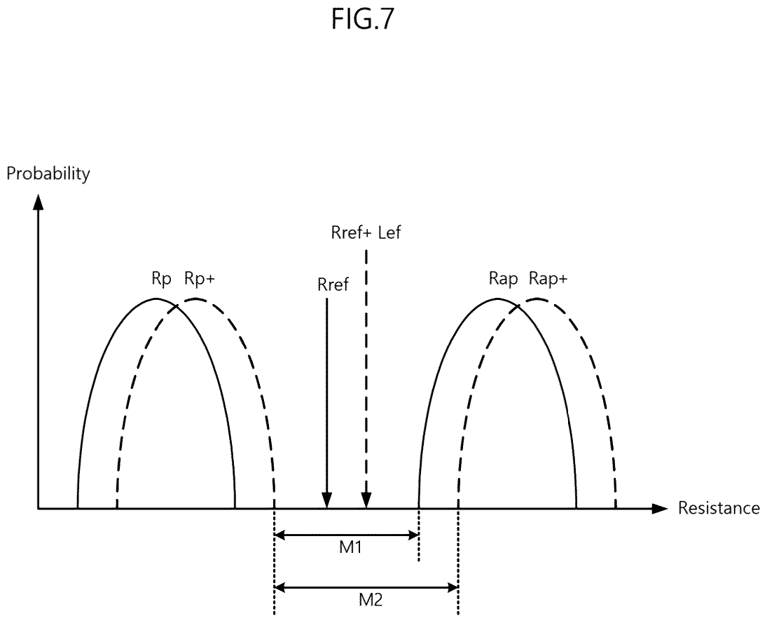

FIG. 7 is a graph for explaining the read margin before and after compensating the offset reference resistance. Referring to FIG. 7, M1 is the read margin before compensating the offset reference resistance, and M2 is the read margin after compensating the offset reference resistance. The read offset compensator 2000 may improve the read margin by M2-M1 after compensating the offset reference resistance.

The memory device 1100 may perform a read operation on data 0 and data 1 using a normal reference resistance Rref during a read operation. The resistance distribution of the memory device 1000 may change due to mismatch in MTJ resistance or S/A resistance. The read margin of the memory device 1100 may be reduced to M1 due to mismatch, etc.

The memory device 1100 may compensate the reference resistance Rref by the local resistance Lef1 calculated during the offset reference resistance compensation operation. The memory device 1100 may compensate for each sense amplifier to have an individual local resistance. The memory device 1100 may improve the read margin during a read operation.

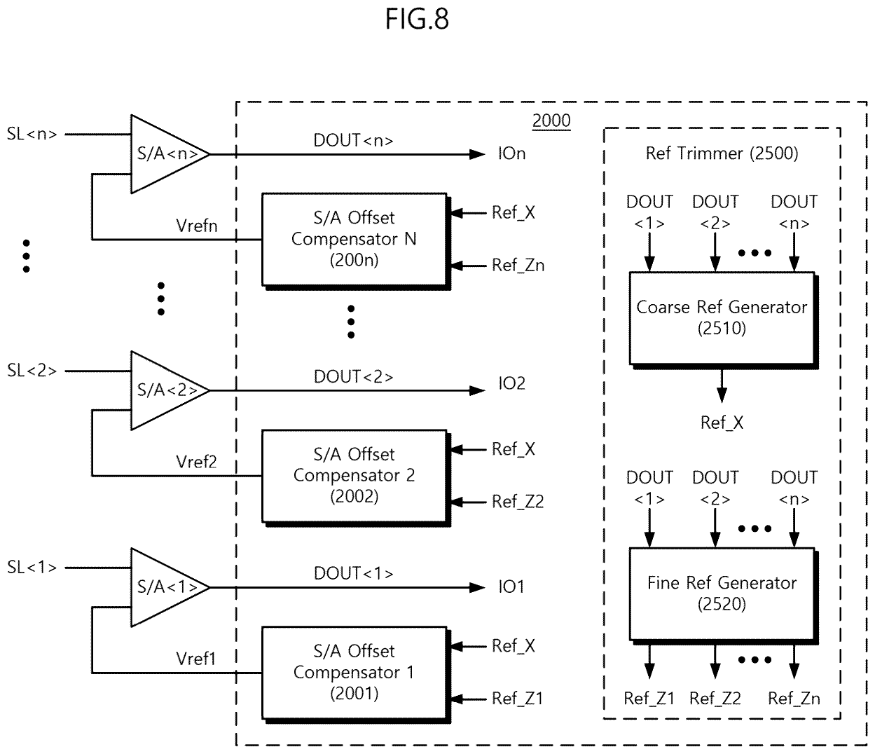

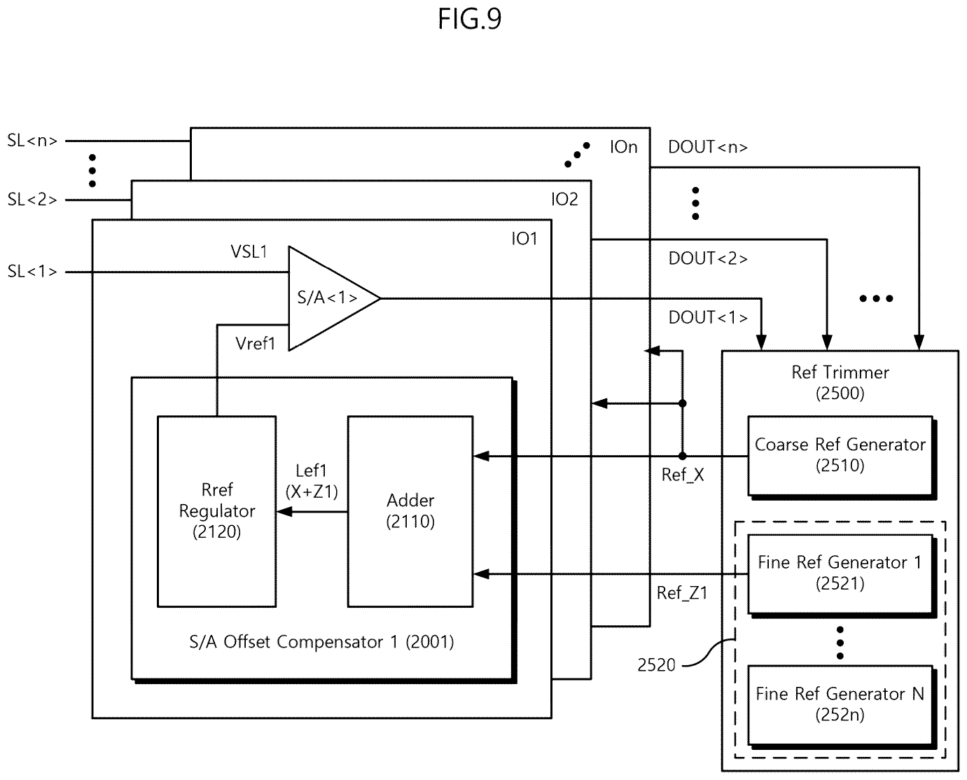

FIG. 8 is a block diagram illustrating an example embodiment of the read offset compensator shown in FIG. 2. Referring to FIG. 8, the read offset compensator 2000 may include first to N-th sense amplifier offset compensators 2001 to 200n and an offset reference resistance trimmer 2500 (referred to as “Ref Trimming Unit 2500” in FIGS. 8 and 9). The offset reference resistance trimmer 2500 may include a coarse offset reference resistance generator 2510 and a fine offset reference resistance generator 2520.

The read offset compensator 2000 may provide first to n-th reference voltages Vref1 to Vrefn to first to n-th sense amplifiers (S/A<i>; i=1 to n). The read offset compensator 2000 may receive offset reference resistances from the coarse offset reference resistance generator 2510 and the fine offset reference resistance generator 2520, and may adjust the first to n-th reference voltages Vref1 to Vrefn.

The first sense amplifier offset compensator 2001 may receive the coarse offset reference resistance Ref_X and the first fine offset reference resistance Ref_Z1 and may adjust the offset reference resistance. The first sense amplifier offset compensator 2001 may adjust the first reference voltage Vref1 by controlling the offset reference resistance.

The second sense amplifier offset compensator 2002 may receive the coarse offset reference resistance Ref_X and the second fine offset reference resistance Ref_Z2 and may adjust the offset reference resistance. The second sense amplifier offset compensator 2002 may adjust the second reference voltage Vref2 by controlling the offset reference resistance.

The N-th sense amplifier offset compensator 200n may receive the coarse offset reference resistance Ref_X and the n-th fine offset reference resistance Ref_Zn, and may adjust the n-th reference voltage Vrefn. The N-th sense amplifier offset compensator 200n may adjust the n-th reference voltage Vrefn by controlling the offset reference resistance.

An offset reference resistance trimmer 2500 may generate offset reference resistances. The offset reference resistances may be determined through an offset compensation operation. The offset reference resistance trimmer 2500 may provide a coarse offset reference resistance Ref_X and a fine offset reference resistance (Ref_Z1 to Ref_Zn) to the first to N-th sense amplifier offset compensators 2001 to 200n.

The coarse offset reference resistance generator 2510 may receive first to n-th output data (DOUT<i>; i=1 to n) from the first to n-th sense amplifiers (S/A<i>; i=1 to n), and generate the coarse offset reference resistance Ref_X. The coarse offset reference resistance Ref_X may be provided to the first to N-th sense amplifier offset compensators 2001 to 200n.

The fine offset reference resistance generator 2520 may receive first to n-th output data (DOUT<i>; i=1 to n) from the first to n-th sense amplifiers (S/A<i>; i=1 to n) and generate first to n-th fine offset reference resistances Ref_Z1 to Ref_Zn. The first fine offset reference resistance Ref_Z1 may be provided to the first sense amplifier offset compensator 2001, the second fine offset reference resistance Ref_Z2 may be provided to the second sense amplifier offset compensator 2002, and the n-th fine offset reference resistance Ref_Zn may be provided to the n-th sense amplifier offset compensator 200n.

FIG. 9 is a block diagram illustrating an example embodiment of the first sense amplifier offset compensator shown in FIG. 8.

Referring to FIG. 9, the first sense amplifier offset compensator 2001 may include an adder 2110 and a reference resistance regulator 2120 (referred to as “Rref Regulator” in FIG. 9).

The first sense amplifier offset compensator 2001 may receive the coarse offset reference resistance Ref_X and the first fine offset reference resistance Ref_Z1 and may adjust the offset reference resistance. The first sense amplifier offset compensator 2001 may adjust the first reference voltage Vref1 by controlling the offset reference resistance.

The adder 2110 may receive the coarse offset reference resistance Ref_X and the first fine offset reference resistance Ref_Z1 from the offset reference resistance trimmer 2500, and generate a first local resistance (Lef1) for adjusting the first reference voltage Vref1. The first local resistance Lef1 may be calculated using the coarse offset reference resistance Ref_X and the first fine offset reference resistance Ref_Z1.

The reference resistance regulator 2120 may receive the first local resistance Lef1 from the adder 2110 and determine an offset reference resistance. The reference resistance regulator 2120 may adjust the first reference voltage Vref1 by determining the offset reference resistance. The first reference voltage Vref1 may be provided to the first sense amplifier S/A<1>.

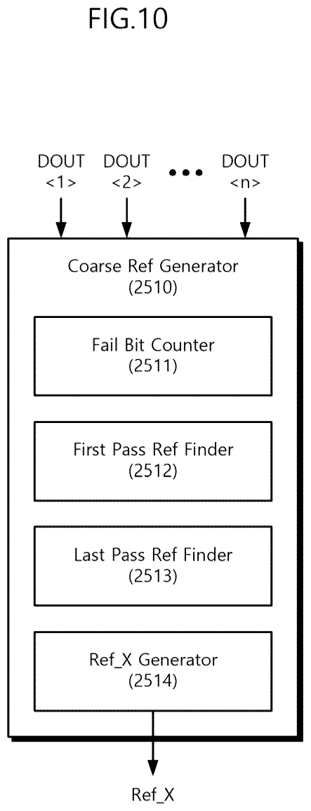

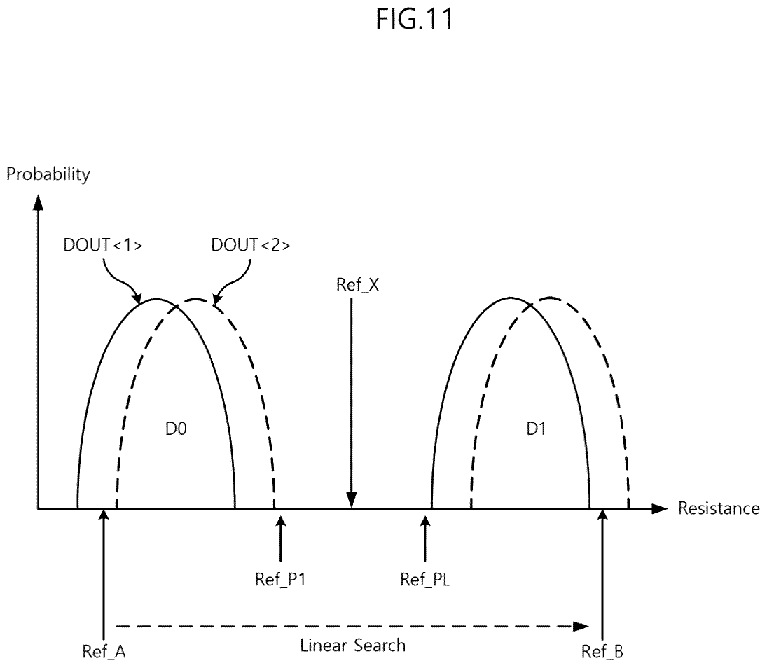

FIGS. 10 and 11 are block diagrams and graphs illustrating the configuration and operation method of the coarse offset reference resistance generator shown in FIG. 9. Referring to FIG. 10, the coarse offset reference resistance generator 2510 may include a fail bit counter 2511, a first pass Ref finder 2512, a last pass Ref finder 2513, and a Ref_X generator 2514.

The fail bit counter 2511 may receive first to n-th output data (DOUT<1>˜DOUT<n>) and search for the number of fail bits. For example, referring to FIG. 11, the first and second output data DOUT<1> and DOUT<2> may be data output from a plurality of memory cells of the memory cell array 1110.

Assuming that data 0 and/or data 1 are stored in the memory cells, the first and second output data (DOUT<1>, DOUT<2>) may have a D0 and/or D1 resistance distribution. The first and second output data (DOUT<1>, DOUT<2>) may have different resistance distributions as shown in FIG. 11 due to mismatch in sense amplifiers, etc. The resistance distribution of the first output data (DOUT<1>) is indicated by a solid line, and the resistance distribution of the second output data (DOUT<2>) is indicated by a dotted line. This difference in resistance distribution may reduce read margin.

The fail bit counter 2511 may search for the number of fail bits while changing the offset reference resistance Ref to improve the read margin due to differences in resistance distribution. Referring to FIG. 11, the fail bit counter 2511 may search for the number of fail bits while sequentially changing the offset reference resistance from the A offset reference resistance Ref_A to the B offset reference resistance Ref_B. This search method is called linear search.

The fail bit counter 2511 may use other search methods in addition to the linear search. For example, the fail bit counter 2511 may perform a binary search. The binary search is a search method that continuously divides the search section in half. The binary search may be searched quickly because the search section is divided in half.

The first pass Ref finder 2512 may receive the number of fail bits from the fail bit counter 2511 and find the offset reference resistance Ref_P1 that generates the first pass result. Here, the pass result may mean that the number of fail bits is 0. The pass result may be defined as the number of fail bits being less than a certain value. For example, the first pass Ref finder 2412 may define the offset reference resistance at which the number of fail bits is 2 or less as Ref_P1.

The last pass Ref finder 2513 may find the offset reference resistance Ref_PL that generates the last pass result after Ref_P1. The pass result may be defined as the number of fail bits being less than or equal to a certain value. For example, the last pass Ref finder 2413 may define the last offset reference resistance at which the number of fail bits is 2 or less as Ref_PL.

The Ref_X generator 2514 may generate a coarse offset reference voltage Ref_X using Ref_P1 and Ref_PL. For example, the Ref_X generator 2514 may generate Ref_X using the average value of Ref_P1 and Ref_PL. The coarse offset reference resistance generator 2510 may provide Ref_X to the first to N-th sense amplifier offset compensators 2001 to 200n.

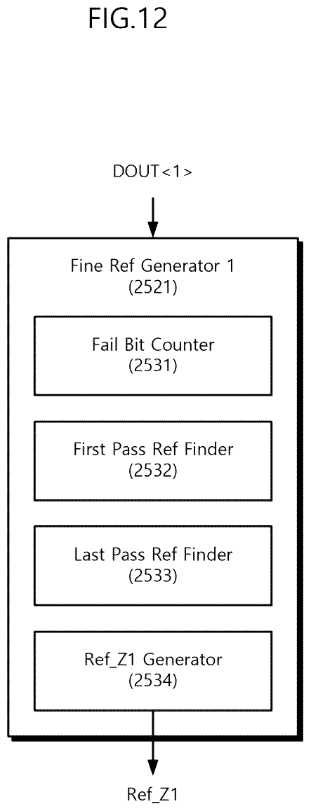

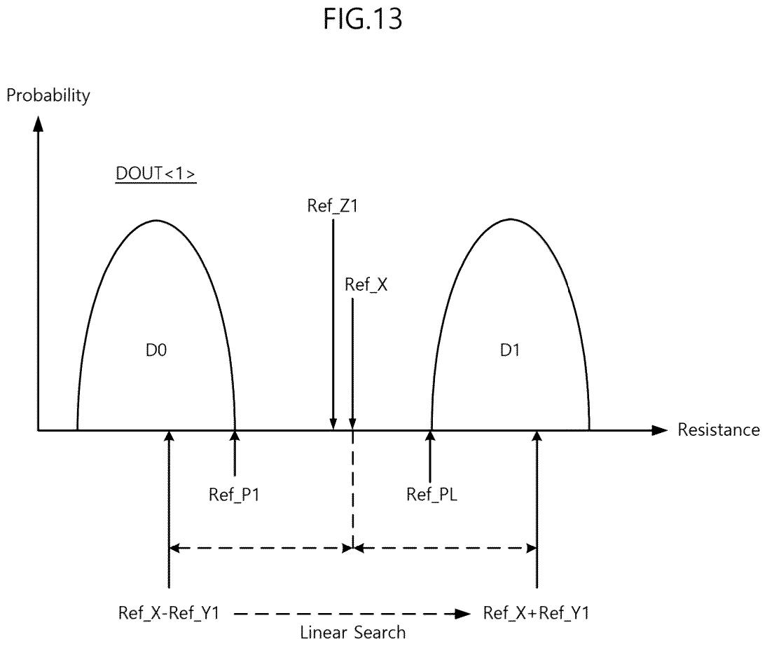

FIGS. 12 and 13 are block diagrams and graphs illustrating the configuration and operation method of the first fine offset reference resistance generator shown in FIG. 9. Referring to FIG. 12, the first fine offset reference resistance generator 2521 may include a fail bit counter 2531, a first pass Ref finder 2532, a last pass Ref finder 2533, and a Ref_Z1 generator 2534.

The fail bit counter 2531 may receive first output data DOUT<1> and search for the number of fail bits. Referring to FIG. 13, first output data DOUT<1> may be data output from a plurality of memory cells of the memory cell array 1110. Assuming that data 0 and/or data 1 are stored in memory cells, the first output data DOUT<1> may have a DO and/or D1 resistance distribution.

The fail bit counter 2531 may search for the number of fail bits while changing the offset reference resistance Ref between −Ref_Y1 and +Ref_Y1 based on Ref_X. The fail bit counter 2531 may search for the number of fail bits while sequentially changing the offset reference resistance from Ref_X−Ref_Y1 to Ref_X+Ref_Y1. The fail bit counter 2531 may perform binary search instead of linear search.

The first pass Ref finder 2532 may receive the number of fail bits from the fail bit counter 2531 and find the offset reference resistance Ref_P1 that generates the first pass result. The first pass Ref finder 2432 may define the offset reference resistance at which the number of fail bits is output below a certain value as Ref_P1.

The last pass Ref finder 2533 may find the offset reference resistance Ref_PL that generates the last pass result after Ref_P1. The pass result may be defined as the number of fail bits being less than or equal to a certain value. For example, the last pass Ref finder 2433 may define the last offset reference resistance at which the number of fail bits is 2 or less as Ref_PL.

The Ref_Z1 generator 2534 may generate the first fine offset reference voltage Ref_Z1 using Ref_P1 and Ref_PL. For example, the Ref_Z1 generator 2514 may generate Ref_Z1 using the average value of Ref_P1 and Ref_PL. The first fine offset reference resistance generator 2521 may provide Ref_Z1 to the first sense amplifier offset compensator 2001.

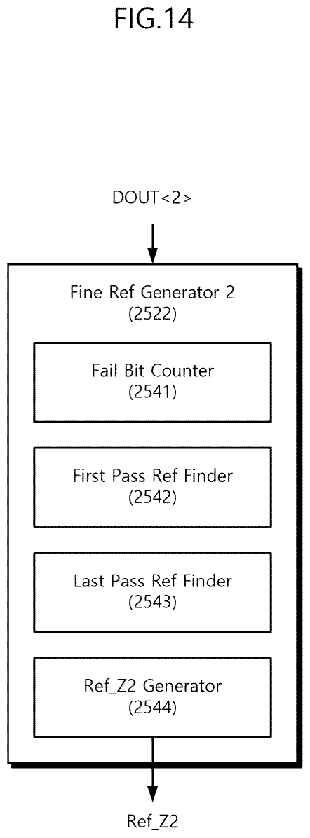

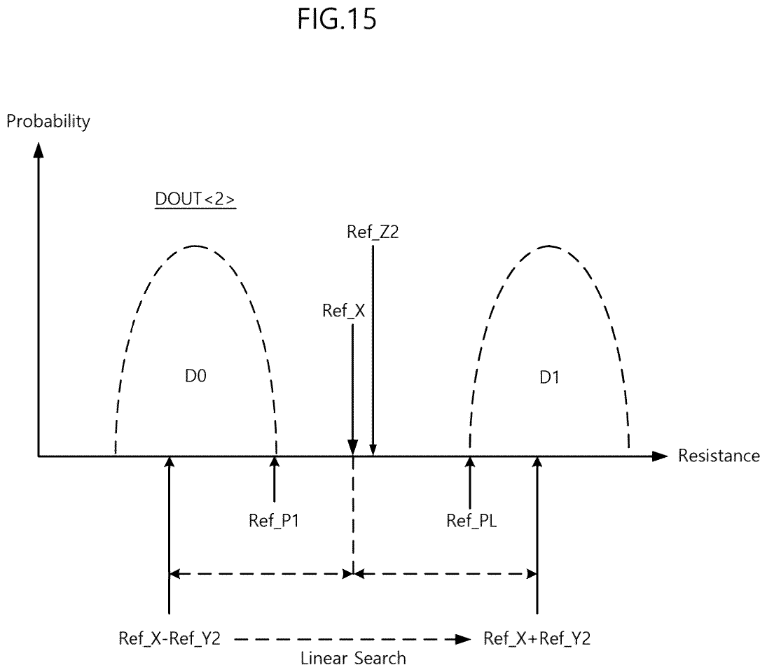

FIGS. 14 and 15 are block diagrams and graphs illustrating the configuration and operation method of the second fine offset reference resistance generator shown in FIG. 9. Referring to FIG. 14, the second fine offset reference resistance generator 2522 may include a fail bit counter 2541, a first pass Ref finder 2542, a last pass Ref finder 2543, and a Ref_Z2 generator 2544.

The fail bit counter 2541 may receive second output data DOUT<2> and search for the number of fail bits. The fail bit counter 2541 may search for the number of fail bits while changing the offset reference resistance Ref between −Ref_Y2 and +Ref_Y2 based on Ref_X. Here, Y2 may be the same as or different from Y1 shown in FIG. 13.

The first pass Ref finder 2542 may receive the number of fail bits from the fail bit counter 2541 and may find the offset reference resistance Ref_P1 that generates the first pass result. The first pass Ref finder 2542 may define the offset reference resistance at which the number of fail bits is output below a certain value as Ref_P1.

The last pass Ref finder 2543 may find the offset reference resistance Ref_PL that generates the last pass result after Ref_P1. The pass result may be defined as the number of fail bits being less than or equal to a certain value. For example, the last pass Ref finder 2543 may define the last offset reference resistance at which the number of fail bits is 2 or less as Ref_PL.

The Ref_Z2 generator 2544 may generate a second fine offset reference voltage Ref_Z2 using Ref_P1 and Ref_PL. For example, the Ref_Z2 generator 2544 may generate Ref_Z2 using the average value of Ref_P1 and Ref_PL. The second fine offset reference resistance generator 2522 may provide Ref_Z2 to the second sense amplifier offset compensator 2002.

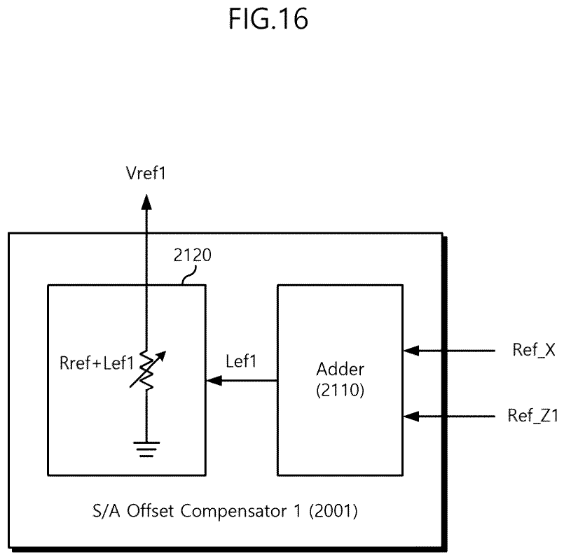

FIG. 16 is a block diagram illustrating an example embodiment of the first sense amplifier offset compensator shown in FIG. 9. Referring to FIG. 16, the first sense amplifier offset compensator 2001 may include an adder 2110 and a reference resistance regulator 2120.

The adder 2110 may receive Ref_X and Ref_Z1 as input and generate a first local resistance Lef1 to adjust the first reference voltage Vref1. The adder 2110 may calculate the first local resistance Lef1 using Ref_X and Ref_Z1. For example, the adder 2110 may generate the first local resistance Lef1 using the average value of Ref_X and Ref_Z1.

The reference resistance regulator 2120 may receive the first local resistance Lef1 from the adder 2110 and determine an offset reference resistance. The reference resistance regulator 2120 may adjust the first reference voltage Vref1 by determining the offset reference resistance. The first reference voltage Vref1 may be provided to the first sense amplifier S/A<1>.

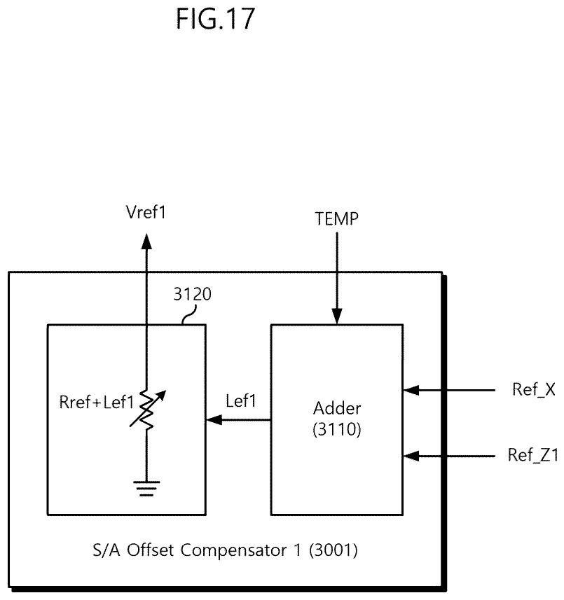

FIG. 17 is a block diagram illustrating a modified example embodiment of the first sense amplifier offset compensator shown in FIG. 16. Referring to FIG. 17, the first sense amplifier offset compensator 3001 may include an adder 3110 and a reference resistance regulator 3120. MTJ devices and sense amplifiers may experience reduced resistance and off-cell leakage depending on temperature. The read margin of the memory device 1100 may be narrowed due to device mismatch and reference resistance characteristics.

The adder 3110 may receive Ref_X, Ref_Z1, and a temperature compensation signal TEMP and generate a first local resistance Lef1 to adjust the first reference voltage Vref1. The adder 3110 may calculate the first local resistance Lef1 using Ref_X, Ref_Z1, and TEMP. For example, the adder 3110 may generate the first local resistance Lef1 by applying temperature compensation to the average value of Ref_X and Ref_Z1.

The reference resistance regulator 3120 may receive the temperature-compensated first local resistance Lef1 from the adder 3110 and determine an offset reference resistance. The reference resistance regulator 3120 may adjust the first reference voltage Vref1 by determining the offset reference resistance. The first reference voltage Vref1 may be provided to the first sense amplifier S/A<1>.

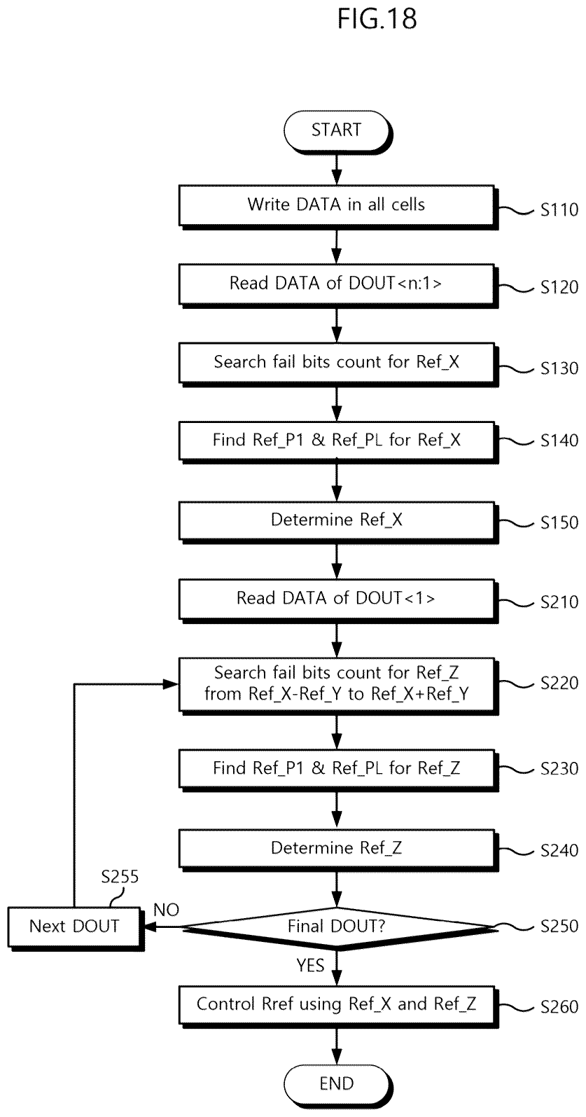

FIG. 18 is a flowchart illustrating an offset reference resistance compensation operation of a memory device according to an embodiment of the present disclosure.

Referring to FIG. 18, at operation S110, the memory device 1100 may write the same data to all memory cells. For example, the memory device 1100 may write data 0 to all memory cells.

At operation S120, the memory device 1100 may perform a read operation on all memory cells. The memory device 1100 may read output data DOUT<n:1>.

At operation S130, the memory device 1100 may search for fail bits of output data to find the coarse offset reference resistance Ref_X. Since the expected data is 0 during a read operation, if the output data is not 0, it may be failed.

At operation S140, the memory device 1100 may find the first pass offset reference resistance Ref_P1 and the last pass offset reference resistance Ref_PL through a fail bit search operation for Ref_X. Then, at operation S150, the memory device 1100 may determine Ref_X using Ref_P1 and Ref_PL.

Next, at operation S210, the memory device 1100 may read the first output data DOUT<1> and at operation S220, the memory device may search for fail bits of the output data to find the first fine offset reference resistance Ref_Z1. The memory device 1100 may search from Ref_X-Ref_Y1 to Ref_X+Ref_Y1.

At operation S230, the memory device 1100 may find the first pass offset reference resistance Ref_P1 and the last pass offset reference resistance Ref_PL through a fail bit search operation for Ref_Z1. At operation S240, the memory device 1100 may determine Ref_Z1 using Ref_P1 and Ref_PL.

At operation 250, the memory device 1100 may determine whether it is the last output data. If it is not the last output data (NO), in operation S255, the memory device 1100 may perform operation S220 on the next output data (for example, DOUT<2>). At this time, the Y value may be the same or different.

If it is the last output data (YES) in operation S250, the memory device 1100 may control the reference resistance using Ref_X and Ref_Z in operation S260. The memory device 1100 may adjust the first reference voltage Vref1 by controlling the reference resistance.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A read offset compensator, the read offset compensator comprising:
a coarse offset reference resistance generator configured to:
determine whether a number of fail bits of output data of a memory device is less than or equal to a reference value, and
determine a coarse offset reference resistance based on the number of fail bits of the output data being less than or equal to the reference value;
a first fine offset reference resistance generator configured to:
determine a number of fail bits of first output data of the memory device within a first reference resistance range based on the coarse offset reference resistance,
determine whether the number of fail bits of the first output data is less than or equal to the reference value, and
determine a first fine offset reference resistance based on the number of fail bits of the first output data being less than or equal to the reference value;
a second fine offset reference resistance generator configured to:
determine a number of fail bits of second output data of the memory device within a second reference resistance range based on the coarse offset reference resistance,
determine whether the number of fail bits of the second output data is less than or equal to the reference value, and
determine a second fine offset reference resistance based on the number of fail bits of the second output data being less than or equal to the reference value;
a first sense amplifier offset compensator configured to:
receive the coarse offset reference resistance and the first fine offset reference resistance, and
adjust a first offset reference resistance; and
a second sense amplifier offset compensator configured to:
receive the coarse offset reference resistance and the second fine offset reference resistance, and
adjust a second offset reference resistance,
wherein each sense amplifier offset compensator from the first sense amplifier offset compensator to the second sense amplifier offset compensator is further configured to:
calculate a respective local resistance for compensating a respective offset reference resistance for a respective sense amplifier during offset reference resistance compensation, and
adjust a respective reference resistance for a read operation based on the respective local resistance.

2. The read offset compensator of claim 1, wherein the first sense amplifier offset compensator comprises:
an adder configured to calculate a first local resistance using the coarse offset reference resistance and the first fine offset reference resistance; and
a reference resistance regulator configured to receive the first local resistance from the adder and adjust a first reference resistance.

3. The read offset compensator of claim 2, wherein the reference resistance regulator is further configured to:
adjust a first reference voltage by controlling the first reference resistance for the read operation, and
provide a first adjusted reference voltage to a first sense amplifier.

4. The read offset compensator of claim 1, wherein memory cells of the memory device are written with same data before the offset reference resistance compensation.

5. The read offset compensator of claim 1, wherein the coarse offset reference resistance generator comprises:
a fail bit counter configured to count the number of fail bits of the output data of the memory device;
a Ref_P1 finder configured to search for an offset reference resistance Ref_P1 at which a first pass result is generated while performing a fail bit search operation;
a Ref_PL finder configured to search for an offset reference resistance Ref_PL at which a last pass result is generated after the offset reference resistance Ref_P1; and
a Ref_X generator configured to generate a coarse offset reference resistance Ref_X using the offset reference resistance Ref_P1 and the offset reference resistance Ref_PL.

6. The read offset compensator of claim 5, wherein the fail bit search operation is a linear search or a binary search.

7. The read offset compensator of claim 5, wherein the Ref_X generator calculates the coarse offset reference resistance Ref_X using an average value of the offset reference resistance Ref_P1 and the offset reference resistance Ref_PL.

8. The read offset compensator of claim 5, wherein the second fine offset reference resistance generator is further configured to:
count the number of fail bits of the second output data,
search the offset reference resistance Ref_P1 and the offset reference resistance Ref_PL while performing the fail bit search operation, and
generate the second fine offset reference resistance using the offset reference resistance Ref_P1 and the offset reference resistance Ref_PL, wherein the second fine offset reference resistance is a second fine offset reference resistance Ref_Zn.

9. The read offset compensator of claim 8, wherein the fail bit search operation for the Ref_Zn is linear search or binary search.

10. The read offset compensator of claim 1, wherein each sense amplifier offset compensator from the first sense amplifier offset compensator to the second sense amplifier offset compensator is further configured to:
calculate the respective offset reference resistance with a respective temperature compensation during the offset reference resistance compensation, and
adjust the respective reference resistance for the read operation based on the respective local resistance and the respective temperature compensation.

11. A memory device comprising:
memory cell array comprising a plurality of memory cells;
a row decoder connected to the memory cell array through word lines;
a column decoder connected to the memory cell array through bit lines and source lines;
a sense amplifier configured to read data stored in selected memory cells by detecting the difference between the source line voltage and the reference voltage during a read operation; and
a controller configured to have a read offset compensator for performing an offset reference resistance compensation,
wherein the read offset compensator is configured to:
receive output data from the sense amplifier,
search for a number of fail bits of the output data to determine a coarse offset reference resistance,
detect a number of fail bits of first output data within a first reference resistance range based on the coarse offset reference resistance to determine a first fine offset reference resistance,
search for a number of fail bits of second output data within a second reference resistance range based on the coarse offset reference resistance to determine a second fine offset reference resistance, and
adjust a reference resistance for the read operation using the coarse offset reference resistance and fine offset reference resistances, the fine offset reference resistances comprising resistances from the first fine offset reference resistance to the second fine offset reference resistance.

12. The memory device of claim 11, wherein the read offset compensator comprises:
a first sense amplifier offset compensator configured to:
receive the coarse offset reference resistance and the first fine offset reference resistance; and
adjust a first offset reference resistance; and
a second sense amplifier offset compensator configured to:
receive the coarse offset reference resistance and the second fine offset reference resistance; and
adjust a second offset reference resistance,
wherein each sense amplifier offset compensator from the first sense amplifier offset compensator to the second sense amplifier offset compensator is further configured to:
calculate a respective local resistance for compensating a respective offset reference resistance for a respective sense amplifier during offset reference resistance compensation, and
adjust a respective reference resistance for the read operation based on the respective local resistance.

13. The memory device of claim 12, wherein the second sense amplifier offset compensator comprises:
an adder configured to calculate the local resistance using the coarse offset reference resistance and the second fine offset reference resistance; and
a reference resistance regulator configured to receive the local resistance from the adder and adjust a reference resistance.

14. The memory device of claim 12, wherein the read offset compensator further comprises:
a coarse offset reference resistance generator configured to:
determine whether the number of fail bits of the output data is less than or equal to a reference value; and
determine the coarse offset reference resistance based on the number of fail bits of the output data being less than or equal to the reference value;
a first fine offset reference resistance generator configured to:
search for the number of fail bits of the first output data within the first reference resistance range based on the coarse offset reference resistance;
determine whether the number of fail bits of the first output data is less than or equal to the reference value; and
determine the first fine offset reference resistance based on the number of fail bits of the first output data being less than or equal to the reference value;
a second fine offset reference resistance generator configured to:
search for the number of fail bits of the second output data within the second reference resistance range based on the coarse offset reference resistance;
determine whether the number of fail bits of the second output data is less than or equal to the reference value; and
determine the second fine offset reference resistance based on the number of fail bits of the second output data being less than or equal to the reference value;

15. The memory device of claim 14,
wherein the coarse offset reference resistance generator comprises:
a fail bit counter configured to count the number of fail bits of the output data;
a Ref_P1 finder configured to search for an offset reference resistance Ref_P1 at which a first pass result is generated while performing a fail bit search operation;
a Ref_PL finder configured to search for an offset reference resistance Ref_PL at which a last pass result is generated after the offset reference resistance Ref_P1; and
a Ref_X generator configured to generate a coarse offset reference resistance Ref_X using the offset reference resistance Ref_P1 and the offset reference resistance Ref_PL.

16. The memory device of claim 15,
wherein the second fine offset reference resistance generator if further configured to:
count the number of fail bits of the second output data,
search the offset reference resistance Ref_P1 and the offset reference resistance Ref_PL while performing the fail bit search operation, and
use the offset reference resistance Ref_P1 and the offset reference resistance Ref_PL to generate the second fine offset reference resistance, wherein the second fine offset reference resistance is a second fine offset reference resistance Ref_Zn.

17. The memory device of claim 12,
wherein each sense amplifier offset compensator from the first sense amplifier offset compensator to the second sense amplifier offset compensator is further configured to:
calculate the respective offset reference resistance with a respective temperature compensation during the offset reference resistance compensation, and
adjust the respective reference resistance for the read operation based on the respective local resistance and the respective temperature compensation.

18. An offset reference resistance compensation method for a memory device, the method being executed by at least one processor, and the method comprising:
searching for a number of fail bits of output data output from a memory cell array of the memory device;
determining a coarse offset reference resistance;
searching for a number of fail bits of a first output data within a first reference resistance range based on the coarse offset reference resistance,
determining a first fine offset reference resistance;
searching for a number of fail bits of the second output data within a second reference resistance range based on the coarse offset reference resistance,
determining a second fine offset reference resistance; and
adjusting a reference resistance for a read operation using the coarse offset reference resistance and fine offset reference resistances, the fine offset reference resistances comprising resistances from the first fine offset reference resistance to the second fine offset reference resistance.

19. The method of claim 18, wherein during the determining the coarse offset reference resistance, a linear search or binary search is used to search whether the number of fail bits of the output data is less than or equal to a reference value, and the coarse offset reference resistance is determined according to the search result.

20. The method of claim 18, wherein during the determining the second fine offset reference resistance, a linear search or binary search is used to search whether the number of fail bits of the second output data is less than or equal to a reference value, and the second fine offset reference resistance is determined according to the search result.
